(19) United States
(12) Patent Application Publication
(10) Pub. No.: US 2008/0204994 A1
(43) Pub. Date: Aug. 28, 2008

(54) Hard disk tray

(75) Inventor: Ah-Jee Wang, Taipei City (TW)

Correspondence Address: BACON & THOMAS, PLLC, 625 SLATERS LANE, FOURTH FLOOR, ALEXANDRIA, VA, 22314, US

(73) Assignee: D-Link Corporation, Taipei City (TW)

(21) Appl. No.: 11/709,806

(22) Filed: Feb. 23, 2007

(51) Int. Cl. H05K 7/00

(52) U.S. Cl. 361/685

(57) ABSTRACT

A hard disk tray being pluggable in a plug slot of a server, includes a load plate, a first guide plate, a second guide plate, a grasp portion and a light guide portion. The first guide plate is located at one side of the load plate, for coupling with a guide slot defined in one side of the plug slot. The second guide plate is located at the other side of the load plate, for coupling with a guide slot formed in the other side of the plug slot. The grasp portion is located at an end of the load plate that faces away from the server, for positioning the hard disk tray within the plug slot. The light guide portion is enclosed between the other side of the load plate and the second guide plate, and the light guide portion has two ends extending to two ends of the second guide plate.

### FIELD OF THE INVENTION

The present invention relates to hard disk trays, and more particular, to a hard disk tray having a simple structure and a light weight.

### BACKGROUND OF THE INVENTION

With information industry booming nowadays, computers are widely used, not only in family lives, office automations, but also in the fabrication process and production control in the manufacturing industry. However, the requirement for computer performance under different circumstances is different. In particular, servers used in factories must meet industrial standard, especially in terms of features like heat-resistance, shock-resistance and operation stability, which is stricter for industrial standard servers than those of home computers and office computers.

Generally, in the production control of a factory or an even bigger control environment, it is necessary to use multiple industrial standard servers for controlling, and it is often necessary to transport or move the servers to another place. Therefore, to address this issue, the servers are usually fitted with a handle for the operator to grasp and pull. In addition, the servers are usually mounted in a rack mount with lateral sliding tracks for facilitating the extraction of servers from the rack mount.

In addition, in order to increase the storage capacity of the servers, manufacturers have developed a conventional server that allows a plurality of hard disks to plug into. Referring to FIG. 1, the server includes a chassis 11 and a plurality of plug-in racks 12. The chassis 11 has a receiving space 111 disposed at one end thereof, and the plug-in racks 12 are mounted side by side within the receiving space 111. Each plug-in rack 12 includes a load plate 121, an operation handle 123, an upper side plate 125 and a lower side plate 127. The load plate 121 has a flange 122 disposed at one end thereof. The operation handle 123 is located at the other end of the load plate 121 that faces away from the flange 122. The upper side plate 125 and the lower side plate 127 are respectively disposed at opposite sides of the load plate 121, the upper side plate 125 is adjacent to a top side of the chassis 11, and the lower side plate 127 is adjacent to a bottom side of the chassis 11. As such, a hard disk 13 positioned between the flange 122, the operation handle 123, the upper side plate 125 and the lower side plate 127 can be mounted into the server along with the plug-in rack 12.

In addition, a flexible printed circuit board 14 is disposed on a surface of the lower side plate 127 that faces toward the upper side plate 125. Two ends of the flexible printed circuit board 14 respectively extend to two ends of the lower side plate 127. The operation handle 123 has two indicator lights 129 disposed at one end of the operation handle 123 adjacent to the lower side plate 127. One end of each indicator light 129 is electrically coupled to one end of the flexible printed circuit board 14, and the other end of each indicator light 129 is exposed and located on one surface of the operation handle 123 that faces away from the load plate 121. When the hard disk 13 is placed in the plug-in rack 12 and the plug-in rack 12 is slid into the receiving space 111 to make the hard disk 13 and the other end of the flexible printed circuit board 14 electrically couple to the server, the server generates a signal and sends the signal to the indicator lights 129 through the flexible printed circuit board 14 to generate light, thereby allowing users to observe the operation status of the hard disk 13.

However, in order to make the plug-in rack 12 strong and durable, the upper side plate 125 and the lower side plate 127 are made into bar-shaped metal blocks, which greatly increases the weight of the plug-in rack 12 and takes up much space within the server. Furthermore, the flexible printed circuit board 14 is directly disposed on the side of the lower side plate 127 that faces toward the upper side plate 125, which also takes up space inside of the plug-in rack 12 where the hard disk 13 resides, therefore, the size of the plug-in rack 12 can not be further reduced. As a result, limited by the size of the plug-in rack 12, the server can only allow a limited number of plug-in racks 12 to fit in. Moreover, when the plug-in rack 12 and the hard disk 13 received therein are to be removed from or assembled into the server, the flexible printed circuit board 14 needs to be disposed and connected to the server again, which causes inconvenience in use. Therefore, how to reduce the size of the plug-in rack 12 for mounting the hard disk 13, avoid the use of complicated components such as the flexible printed circuit board 14, and provide reasonable structure strength at the same time, is an important issue manufacturers need to address currently.

### SUMMARY OF THE INVENTION

Accordingly, to improve the conventional server that allows a plurality of plug-in racks to plug into, and to overcome the bulky and space occupation of the plug-in rack and the shortcomings caused by the flexible printed circuit board, the inventor conducted long-time diligent researches and experiments, and finally developed a hard disk tray of the present invention.

The present invention is directed to a hard disk tray being pluggable into a plug slot of a server. The hard disk tray includes a load plate, a first guide plate, a second guide plate, a grasp portion and a light guide portion. The first guide plate is located at one side of the load plate, for coupling with a guide slot defined in one side of the plug slot. The second guide plate is located at the other side of the load plate, for coupling with a guide slot defined in the other side of the plug slot. The grasp portion is located at an end of the load plate that faces away from the server, for positioning the hard disk tray within the plug slot. The light guide portion is enclosed between the other side of the load plate and the second guide plate, and the light guide portion has two ends extending to two ends of the second guide plate. As such, the hard disk tray is not only convenient to assemble, but also skillfully receives the light guide portion in the limited space within the hard disk tray by means of the second guide plate. This can thus reduce the size of the hard disk tray, allowing the plug slot to receive more hard disk tray.

### BRIEF DESCRIPTION OF THE DRAWINGS

The foregoing aspects, as well as many of the attendant advantages and features of this invention will become more apparent by reference to the following detailed description, when taken in conjunction with the accompanying drawings, wherein:

FIG. 1 is a schematic view of a conventional server that allows a plurality of hard disks to plug into;

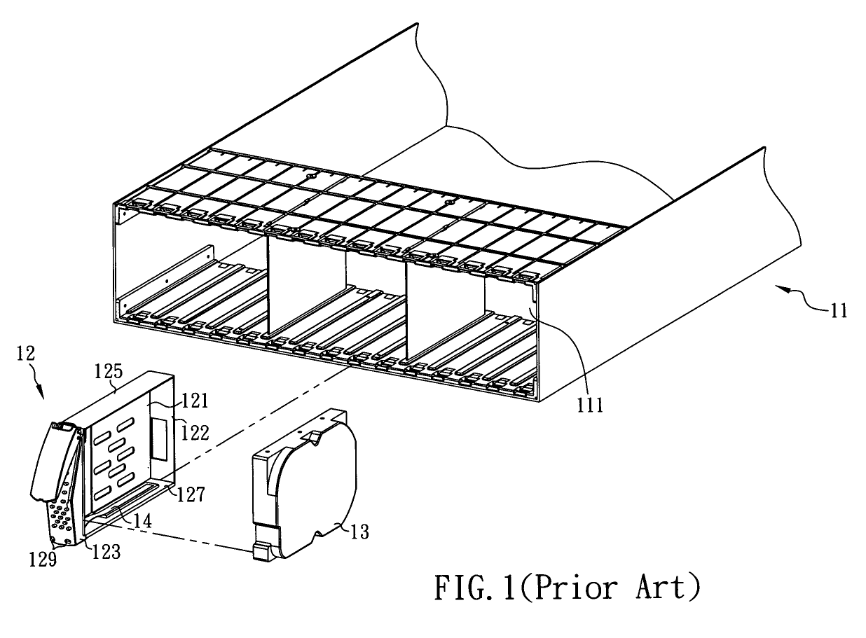

FIG. 2 is an exploded view of a hard disk tray in accordance with the present invention;

FIG. 3 is an exploded view of a grasp portion of the hard disk tray in accordance with the present invention; and

FIG. 4 is a schematic view of a second guide plate of the hard disk tray in accordance with the present invention;

### DESCRIPTION OF THE EMBODIMENTS

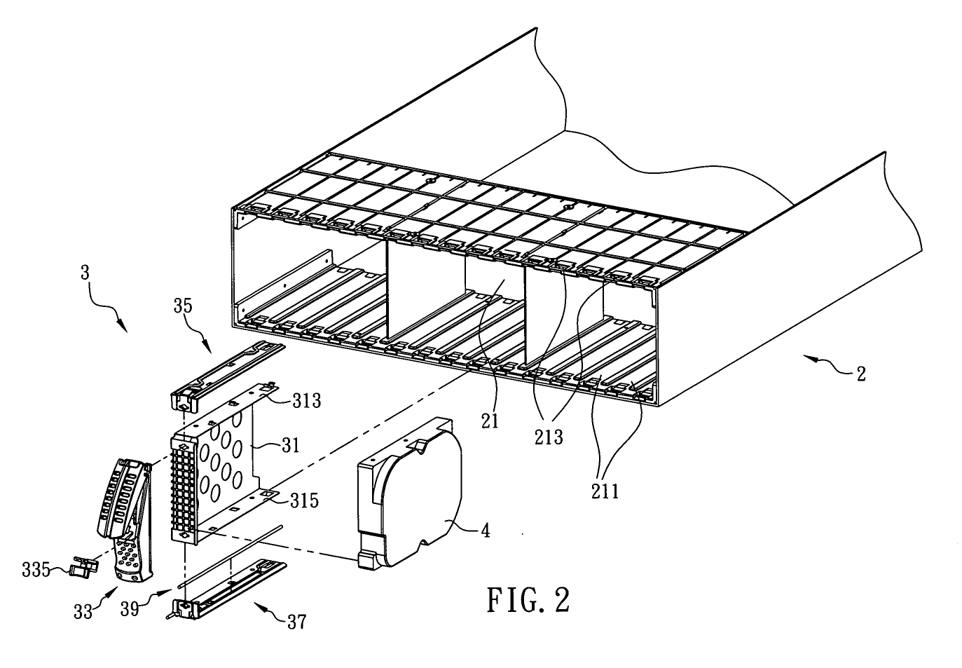

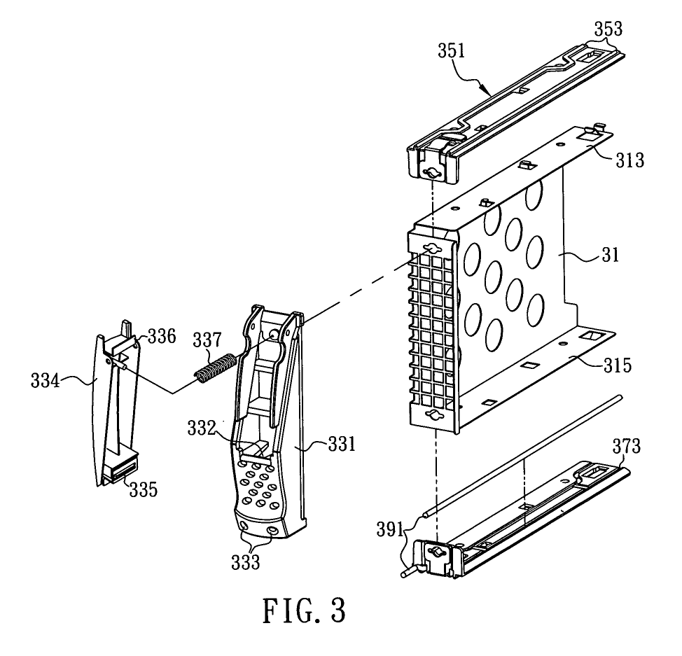

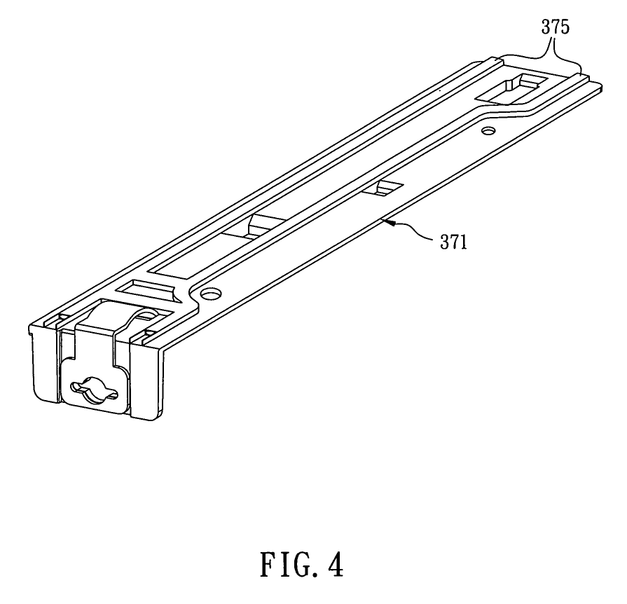

The present invention discloses a hard disk tray. Referring to FIG. 2, the hard disk tray 3 is movably disposed in a plug slot 21 of a server 2. The plug slot 21 is defined at one end of the server 2. The plug slot 21 has one side adjacent to a top surface of the server 2, and the other side adjacent to a bottom surface of the server 2. The plug slot 21 is provided with a plurality of recessed guide slots 211 in two opposite surfaces of the server 2, for allowing a plurality of such hard disk trays 3 to be received side by side in the guide slots 211. The hard disk tray 3 includes a load plate 31, a grasp portion 33, a first guide plate 35, a second guide plate 37 and a light guide portion 39. The load plate 31 includes a first flange 313 disposed at one side thereof, and a second flange 315 disposed at the other side thereof. The load plate 31 receives a hard disk 4 between the first flange 313 and the second flange 315. The grasp portion 33 is located at one end of the load plate 31 that faces away from the server 2, for allowing a user to insert/extract the hard disk tray 3. The first guide plate 35 is located at one side of the first flange 313 that faces away from the second flange 315, and the first guide plate 35 includes a first couple portion 351 (as shown in FIG. 3) at one side of the first guide plate 35 that faces away from the load plate 31. The first couple portion 351 is coupled to the guide slot 211 at one side of the plug slot 21. The second guide plate 37 is located at one side of the second flange 315 that faces away from the first flange 313, and the second guide plate 37 includes a second couple portion 371 (at shown in FIG. 4) at one side of the second guide plate 37 that faces away from the load plate 31. The second couple portion 371 is coupled to the guide slot 211 at the other side of the plug slot 21. The light guide portion 39 is disposed between the second guide plate 37 and the second flange 315, and two ends of the light guide portion 39 extend to two ends of the load plate 31.

When the hard disk tray 3 is to slide into the plug slot 21, with the engagement of the first/second couple portions 351, 371 with the guide slots 211 at two sides of the plug slot 21, the hard disk tray 3 is securely received into the plug slot 21. Besides, with the second couple portion 371 protruding from the side of the second guide plate 37 that faces away from the load plate 31, the second guide plate 37 can form a space in a side thereof that faces toward the load plate 31, for receiving the light guide portion 39 therein. Thus, through the use of the light guide portion 39, the hard disk tray 3 can transmit the light generated by the server 2 to indicate the operation status of the hard disk 4, thereby allowing the user to easily observe the operation status of the hard disk 4. As such, the hard disk tray 3 allows the space to be used effectively by means of the provision of the second couple portion 371, and can thus receive the light guide portion 39 without increasing a size of the hard disk tray 3. In addition, the hard disk tray 3 is of a simple structure and light weight, and can thus overcome the problem caused by conventional bulky plug-in racks. Furthermore, the shortcomings caused by the conventional flexible printed circuit board can be thoroughly overcome by the present invention.

In one embodiment of the present invention, referring again to FIGS. 2 and 3, the light guide portion 39 includes at least one light guide pillar 391. The second guide plate 37 has two channels 373 in the side thereof facing toward the second flange 315, for respectively receiving therein the light guide pillars 391, with an end of each light guide pillar 391 disposed at one end of the load plate 31 facing toward the grasp portion 33, and the other end of each light guide pillar 391 extending to the other end of the load plate 31 facing away from the grasp portion 33. As such, the light guide pillars 391 are enclosed between the second flange 315 and the two channels 373, and after the other end of the light guide pillar 391 receives light source of the server 2, the light guide pillar 391 can completely transmit the light to the end thereof facing toward the grasp portion 33, thereby allowing the user to easily observe the operation status of the hard disk 4. In this embodiment, referring to FIGS. 3 and 4, the first couple portion 351 includes two protruding rails 353. The protruding rails 353 each extend to two ends of the first guide plate 35 (see FIG. 2), and slidably engage with the guide slot 211 at one side of the plug slot 21. Besides, the second couple portion 371 includes two other protruding rails 375. The other protruding rails 375 each extend to two ends of the second guide plate 37, and slidably engage with the guide slot 211 at the other side of the plug slot 21. As such, by configuring the size of width of the guide slots 211 at two sides of the plug slot 21, and engagement between the guide slots 211 and the protruding rails 353, 375, the guide slots 211 and the protruding rails 353, 375 cooperatively form a slide rail assembly, for allowing the hard disk tray 3 to smoothly slide into the plug slot 21.

In this embodiment, referring again to FIGS. 2 through 4, the two channels 373 are formed in one side of the second guide plate 37 and positioned respectively corresponding to the other two protruding rails 375. With the other two protruding rails 375 protruding from one side of the second guide plate 37, the areas of the other side of the second guide plate 37 that correspond to the two other protruding rails 375 are recessed to form the two channels 373. As such, without providing additional space for the light guide pillars 391, the hard disk tray 3 can receive the light guide pillars 391 respectively in the two channels 373.

In this embodiment, referring again to FIGS. 2 and 3, the grasp portion 33 includes a mounting base 331 and an operation handle 334. The mounting base 331 has a bottom surface mounted onto an end surface of the load plate 31, and a top surface forming a first hook portion 332 thereon. The first hook portion 332 is a recessed slot portion. One end of the operation handle 334 is pivotably mounted onto the top surface of the mounting base 331 adjacent to one end thereof, and the other end of the operation handle 334 forms a second hook portion 335. The second hook portion 335 is a clasp button. When the operation handle 334 is pivoted to a position adjacent to the top surface of the mounting base 331, the hook portions 332, 335 are clasped with each other.

In addition, the operation handle 334 includes a hook 336 at one end thereof. When the hook portions 332, 335 are to be clasped with each other, the second hook portion 335 is moved close to the first hook portion 332, thus causing the hook 336 to move and be stuck in a hook slot 213 that is formed in a side of the plug slot 21. Reversely, when the second hook portion 335 is moved and disengaged from the first hook portion 332, the hook 336 can be driven to disengage from the hook slot 213 by moving the operation handle 334, thereby allowing extraction of the hard disk tray 3 out of the plug slot 21. As such, the hard disk tray 3 is received in the plug slot 21 and is locked in the plug slot 21 by the clasp engagement between the hook portions 332, 335.

In this embodiment, referring again to FIGS. 2 and 3, a spring element 337 is disposed between the pivot joint ends of the mounting base 331 and the operation handle 334. The spring element 337 has one end fixedly mounted onto a top side of the mounting base 331, and the other end fixedly mounted onto a side of the operation handle 334 that faces toward the mounting base 331. When the second hook portion 335 disengages from the first hook portion 332, the second hook portion 335 is elastically popped away from the first hook portion 332 under the force of the spring element 337. Simultaneously, the hook 336 disengages from the hook slot 213, which causes the hard disk tray 3 to collide with the server 2 at one side of the plug slot 21, which further drives the hard disk tray 3 to slide a distance away from the plug slot 21. As such, the hard disk 4 is easily removed from the plug slot 21 by the user, which allows the user to become aware that the hard disk tray 3 has not been electrically connected with the server 2.

In this embodiment, referring again to FIGS. 2 and 3, the mounting base 331 has a hole 333 defined adjacent to one end thereof. The hole 333 is configured to receive one end of the light guide pillar 391. When the hard disk tray 3 is received in the plug slot 21 to electrically couple the hard disk 4 to the server 2, the light source generated by the server 2 can be transmitted through the light guide pillar 391, thereby allowing the user to readily observe the operation status of the hard disk 4.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A hard disk tray being pluggable into a plug slot of a server, the hard disk tray comprising:
a load plate, the load plate including a first flange and a second flange formed at two opposite sides thereof, the load plate configured to receive a hard disk between the first flange and the second flange;
a grasp portion located at an end of the load plate that faces away from the server;
a first guide plate located at a surface of the first flange that faces away from the second flange, a surface of the first guide plate that faces away from the load plate including a first couple portion, the first couple portion configured to couple to a side of the plug slot;
a second guide plate located at a surface of the second flange that faces away from the first flange, a surface of the second guide plate that faces away from the load plate including a second couple portion, the second couple portion configured to couple to one other side of the plug slot; and
a light guide portion located between the second guide plate and the second flange, the light guide portion having two ends that extend to two ends of the load plate.

2. The hard disk tray in accordance with claim 1, wherein the light guide portion includes at least one light guide pillar, and one light guide pillar respectively received in two channels formed in a surface of the second guide plate that faces toward the second flange, and the light guide pillar includes one end extending to the grasp portion and another end extending to another end of the load plate.

3. The hard disk tray in accordance with claim 2, wherein the first couple portion includes two protruding rails, the two protruding rails extend to two ends of the first guide plate, and are configured to slidably couple to one side of the plug slot.

4. The hard disk tray in accordance with claim 2, wherein the second couple portion includes two other protruding rails, the two other protruding rails extend to two ends of the second guide plate, and are configured to slidably couple to another side of the plug slot.

5. The hard disk tray in accordance with claim 4, wherein the two channels are defined in a surface of the second guide plate and positioned respectively corresponding to the two other protruding rails.

6. The hard disk tray in accordance with claim 3, wherein the grasp portion comprises:
a mounting base, the mounting base including a bottom surface fixedly mounted onto an end surface of the load plate, and a top surface with a first hook portion formed thereon; and
an operation handle, the operation handle including one end pivotably mounted onto the top surface of the mounting base adjacent to one end thereof, and another end with a second hook portion formed thereon, wherein when the operation handle is pivoted to a position adjacent to the top surface of the mounting base, the first and second hook portions are clasped with each other.

7. The hard disk tray in accordance with claim 5, wherein the grasp portion comprises:
a mounting base, the mounting base including a bottom surface fixedly mounted onto an end surface of the load plate, and a top surface with a first hook portion formed thereon; and
an operation handle, the operation handle including one end pivotably mounted onto the top surface of the mounting base adjacent to one end thereof, and another end with a second hook portion formed thereon, wherein when the operation handle is pivoted to a position adjacent to the top surface of the mounting base, the first and second hook portions are clasped with each other.

8. The hard disk tray in accordance with claim 6, wherein the one end of the operation handle includes a hook, when the first and second hook portions are in a clasped state, the hook engages with a hook slot that disposed at one side of the plug slot.

9. The hard disk tray in accordance with claim 7, wherein the one end of the operation handle includes a hook, when the first and second hook portions are in a clasped state, the hook engages with a hook slot that disposed at one side of the plug slot.

10. The hard disk tray in accordance with claim 8, wherein a spring element is located between the pivot joint ends of the mounting base and the operation handle, the spring element includes one end fixedly mounted onto the top surface of the mounting base, and another end fixedly mounted onto a surface of the operation handle that faces toward the mounting base.

11. The hard disk tray in accordance with claim 9, wherein a spring element is located between the pivot joint ends of the mounting base and the operation handle, the spring element includes one end fixedly mounted onto the top surface of the mounting base, and another end fixedly mounted onto a surface of the operation handle that faces toward the mounting base.

12. The hard disk tray in accordance with claim 10, wherein the first hook portion is a recess slot portion.

13. The hard disk tray in accordance with claim 11, wherein the first hook portion is a recess slot portion.

14. The hard disk tray in accordance with claim 10, wherein the second hook portion is a clasp button.

15. The hard disk tray in accordance with claim 11, wherein the second hook portion is a clasp button.

16. The hard disk tray in accordance with claim 10, wherein the mounting base has at least one hole disposed adjacent to another end thereof, and one end of the light guide pillar extends into the at least one hole.

17. The hard disk tray in accordance with claim 11, wherein the mounting base has at least one hole disposed adjacent to another end thereof, and one end of the light guide pillar extends into the at least one hole.
